(19) United States
(12) Patent Application Publication
(10) Pub. No.: US 2006/0003571 A1
(43) Pub. Date: Jan. 5, 2006

(54) Method for forming contact hole in semiconductor device

(75) Inventors: Min-Suk Lee, Ichon-shi (KR); Sung-Kwon Lee, Ichon-shi (KR); Dong-Duk Lee, Ichon-shi (KR)

Correspondence Address: MCDERMOTT WILL & EMERY LLP, 600 13TH STREET, N.W., WASHINGTON, DC, 20005-3096, US

(73) Assignee: Hynix Semiconductor, Inc., Ichon-shi (KR)

(21) Appl. No.: 11/017,675

(22) Filed: Dec. 22, 2004

(30) Foreign Application Priority Data
Jun. 30, 2004 (KR) 2004-49891

(51) Int. Cl. H01L 21/469

(52) U.S. Cl. 438/618; 438/780; 438/736

(57) ABSTRACT

Disclosed is a method for forming a plurality of contact holes in a semiconductor device. The method includes the steps of: forming an oxide-based layer on a substrate; forming an organic polymer layer on the oxide-based layer; forming a photoresist pattern on the organic polymer layer to form the plurality of contact holes; etching the organic polymer layer by using the photoresist pattern as an etch mask, thereby forming a hard mask; etching the oxide-based layer by using the photoresist pattern and the hard mask as an etch mask; and removing the photoresist pattern and the hard mask by performing a photoresist strip process, thereby obtaining the plurality of contact holes.

### FIELD OF THE INVENTION

The present invention relates to a method for fabricating a semiconductor device; and more particularly, to a method for forming a plurality of contact holes in a semiconductor device by using a self align contact (SAC) etching process.

### DESCRIPTION OF RELATED ARTS

A vertical arrangement structure of a unit device is used as integration of a semiconductor device increases, and a pad or a plug forming technology is used for electrical interconnection of the unit devices. At present, this contact pad forming technology is widely used as for a semiconductor device process technology.

Furthermore, as pitch decreases and a vertical thickness of the pitch increases, there is a lack of an etch margin during performing an etching process, i.e., an etching process for forming a contact between gate electrode patterns. Accordingly, a self align contact (SAC) etching process is introduced to improve an etch selectivity and obtain an etch profile, and the SAC etching process is now used as a typical semiconductor process.

When developing a device with a size equal to or less than approximately 10 nm, a photolithography process using ArF or F₂ light source is required in order to make a fine pattern. However, there produces a pattern deformation at a fluoride based gas mainly used as an etching gas during the SAC etching process. The pattern deformation at the fluoride based gas is happened because of a decrease in a depositing thickness of a photoresist caused by a shortness of a wavelength of the light source used for forming the fine pattern along with a structural problem of the photoresist used for the photolithography process using ArF or F₂ light source.

FIGS. 1A and 1B are photographs of scanning electron microscopy (SEM) in a top view illustrating a pattern deformation generated after performing a conventional SAC etching process during applying a photolithography process using ArF light source.

Referring to FIG. 1, there can be observed wiggling of a pattern which is denoted as ‘A’ and referring to Fig. B, there can be observed striation of a pattern which is denoted as ‘B’ The above pattern deformation can be observed because there is a structural reason that the photoresist for ArF light source does not have a benzene ring structure, and thus the ring structure inside of the photoresist is easily broken.

FIGS. 2A to 2D are diagrams illustrating ring structures of a conventional photoresist used for each light source.

FIG. 2A illustrates a structure of the photoresist for I-line. The structure of the photoresist for I-line has a benzene ring in the center. As for the structure of the photoresist for I-line, an ohnish parameter is approximately 2.5 and a glass temperature (Tg) ranges from approximately 100° C. to approximately 120° C.

FIG. 2B illustrates a structure of ‘SOS-13’ of a photoresist for KrF. As for the structure of ‘SOS-13’, there is a benzene ring in the center, the ohnish parameter is approximately 2.7 and the Tg ranges from approximately 100° C. to approximately 140° C.

FIG. 2C illustrates a structure of ‘SASK68C2’ of a photoresist for ArF. As for the structure of ‘SASK68C2’, there is not a benzene ring in the center, the ohnish parameter is approximately 3.2 and the Tg ranges from approximately 170° C. to approximately 180° C.

FIG. 2D illustrates a structure of ‘PAR-101’ of a photoresist for ArF. As for the structure of ‘PAR-101’, there is not a benzene ring in the center, the ohnish parameter is approximately 3.7 and the Tg ranges from approximately 170° C. to approximately 180° C.

Herein, the ohnish parameter is a parameter representing an etching tolerance of a material. As a value of the ohnish parameter becomes larger, the etching tolerance becomes weaker. Accordingly, when using the photoresist for ArF and F₂ that are photo-exposure materials of a next generation for the photolithography process, the photoresist pattern deformation becomes serious during the SAC etching process.

FIG. 3 is a photograph of SEM in a top view illustrating a collapsing state of a conventional photoresist pattern.

In case of making a thickness of the photoresist thick to overcome a weak etching tolerance, the photoresist pattern collapses as denoted in ‘C’ of FIG. 3.

FIG. 4 is a flow chart illustrating a conventional SAC etching process. With reference to the flow chart, the conventional SAC etching process will be explained.

First, a conductive pattern is formed on a gate electrode and then, an etch stop layer is formed on the conductive pattern at step S401. The etch stop layer is made of a nitride layer based insulation layer used for a typical SAC etching process. Subsequently, an inter-layer insulation layer is deposited on all sides at step S402. The inter-layer insulation layer is made of a typical oxide based material layer. Subsequently, an upper portion of the inter-layer insulation layer is planarized during the photolithography process in order to prevent a pattern defect at step S403. At this time, the inter-layer insulation layer can be removed until the etch stop layer is exposed to decrease a portion which will be etched by a subsequent SAC etching process.

Subsequently, the photoresist pattern, i.e., a photoresist (PR) mask for the SAC etching process, is formed by performing the photolithography process using ArF or F₂ light source at step S404. Then, a contact hole is formed by performing the SAC etching process etching the inter-layer insulation layer with use of the photoresist pattern as an etch mask. At this time, an etch stop layer typically remains on a region where contact will be made later.

Subsequently, a remaining photoresist pattern is removed through a PR strip process and an etch by-product and an etch residual product are removed by using a cleaning process at step S406. Next, a contact open process removing the etch stop layer is performed at step S407. Then, the etch by-product generated during the contact open process is removed by performing the cleaning process.

Meanwhile, in case of applying the photolithography process of a high resolution using ArF or F₂ light source to the SAC etching process, the above described problems are produced.

Accordingly, a hard mask is introduced to overcome the problems.

FIG. 5 is a flowchart illustrating an improved conventional SAC etching process. With reference to the flow chart, an improved SAC etching process in accordance with the prior art will be explained.

First, a conductive pattern such as a gate electrode is formed and an etch stop layer is formed thereon at step S501. Subsequently, an inter-layer insulation layer is deposited on all sides at step S502. The inter-layer insulation layer is made of a typical oxide layer based material layer. Next, an upper portion of the inter-layer insulation layer is planarized during a photolithography process to prevent a pattern defect at step S503. At this time, the inter-layer insulation layer can be removed until the etch stop layer is exposed to decrease a portion which will be etched by a subsequent SAC etching process.

Next, a polysilicon layer or a tungsten layer that will be used for a hard mask is deposited on the inter-layer insulation layer at step S504. There is an effect of preventing a pattern deformation caused by a weak etch tolerance of the photoresist for ArF if using the polysilicon layer and the tungsten layer as the hard mask because the polysilicon layer and the tungsten layer have a relatively high etch selectivity with respect to the oxide layer.

Next, a photoresist pattern, i.e., a PR mask for the SAC etching process, is formed by performing the photolithography process using ArF or F₂ light source at step S505. A hard mask defining a region where the SAC is formed is formed by etching a material layer for the hard mask, i.e., the polysilicon layer or the tungsten layer, with use of the photoresist pattern as an etch mask at step S506.

Next, a remaining photoresist pattern is removed through a PR strip process and an etch by-product and an etch residual product are removed through a cleaning process at step S507.

Subsequently, a contact hole is formed by performing the SAC etching process etching the inter-layer insulation layer by using the hard mask as the etch mask at step S508. At this time, the etch stop layer typically remains on a region where contact will be made later. Meanwhile, the step S507 can be performed after performing the SAC etching process.

Next, a contact open process removing the etch stop layer is employed and then, the hard mask is removed at step S509.

Meanwhile, the hard mask can be removed before removing the etch stop layer and the hard mask also can be removed by employing a subsequent plug isolation process without employing a special hard mask removing process.

Subsequently, the etch by-product generated during the contact open process is removed by performing the cleaning process at step S510.

The above improved prior art attribute to prevent a pattern deformation, thereby producing a fine pattern by using the tungsten layer and the polysilicon layer as a hard mask. Herein, a nitride layer can be used as the hard mask material.

However, when using the above described hard mask material, there is a disadvantage of certainly removing the hard mask after forming the contact hole in order to form a plug applying a selective epitaxial growth method used for a device requiring much higher conductivity.

Furthermore, in case of etching the oxide layer which is a main material to form the inter-layer insulation layer, a selective ratio between the photoresist and the oxide layer or in case of using the polysilicon layer, the tungsten layer or the nitride layer as the hard mask, the selective ratio between the polysilicon layer, the tungsten layer or the nitride layer and the oxide layer can hardly meet a selective ratio, i.e., a selective ratio required at a design rule with a size equal to or less than approximately 100 nm and with a size equal to or less than approximately 80 nm, equal to or greater than several tens to one to the fluoride gas.

### SUMMARY OF THE INVENTION

It is, therefore, an object of the present invention to provide a method for forming a plurality of contact holes in a semiconductor device capable of maximizing a selective ratio of an oxide layer used as an inter-layer insulation layer during an etching process requiring a high resolution and simplifying a process.

In accordance with one aspect of the present invention, there is provides a method for forming a plurality of contact holes in a semiconductor device, including the steps of: forming an oxide-based layer on a substrate; forming an organic polymer layer on the oxide-based layer; forming a photoresist pattern on the organic polymer layer to form the plurality of contact holes; etching the organic polymer layer by using the photoresist pattern as an etch mask, thereby forming a hard mask; etching the oxide-based layer by using the photoresist pattern and the hard mask as an etch mask; and removing the photoresist pattern and the hard mask by performing a photoresist strip process, thereby obtaining the plurality of contact holes.

In accordance with another aspect of the present invention, there is provides a method for forming a plurality of contact holes in a semiconductor device, including the steps of: forming a plurality of conductive patterns on a conductive region; forming an oxide-based inter-layer insulation layer on the resulting structure including the plurality of conductive patterns; forming an organic polymer layer on the oxide-based inter-layer insulation layer; forming a photoresist pattern on the organic polymer layer to form the plurality of contact holes; etching the organic polymer layer by using the photoresist pattern as an etch mask, thereby forming a hard mask; etching the inter-layer insulation layer with use of the photoresist pattern and the hard mask as the etch mask; and removing the photoresist pattern and the hard mask by performing a photoresist strip process, thereby obtaining the plurality of contact holes.

In accordance with further aspect of the present invention, there is provides a method for forming a plurality of contact holes in a semiconductor device, including the steps of: forming a plurality of gate electrode patterns on a substrate; forming a nitride-based etch stop layer on the resulting structure including the plurality of gate electrode patterns; forming an oxide-based inter-layer insulation layer on the resulting structure including the nitride-based etch stop layer; forming an organic polymer layer on the oxide-based inter-layer insulation layer; forming a photoresist pattern on the organic polymer layer as a contact mask; forming the organic polymer layer by using the photoresist pattern as an etch mask, thereby obtaining a hard mask; etching the oxide-based inter-layer insulation layer by using the photoresist pattern and the hard mask as an etch mask; removing the photoresist pattern and the hard mask by employing a photoresist strip process; and opening the substrate within the plurality of contact holes by removing the nitride-based etch stop layer, thereby obtaining the plurality of contact holes.

### BRIEF DESCRIPTION OF THE DRAWINGS

The above and other objects and features of the present invention will become better understood with respect to the following description of the preferred embodiments given in conjunction with the accompanying drawings, in which:

FIGS. 1A and 1B are photographs of scanning electron microscopy (SEM) in a top view illustrating a pattern deformation generated after performing a conventional SAC etching process during applying a photolithography process using ArF light source;

FIGS. 2A to 2D are diagrams illustrating ring structures of a conventional photoresist used for each light source;

FIG. 3 is a photograph of SEM in a top view illustrating a collapsing state of a conventional photoresist pattern;

FIG. 4 is a flow chart illustrating a conventional SAC etching process;

FIG. 5 is a flow chart illustrating an improved conventional SAC etching process;

FIG. 6 is a flow chart illustrating a SAC etching process in accordance with the present invention; and

FIGS. 7A to 7E are diagrams illustrating a process for forming a plurality of contact holes for a plurality of cell contacts in a semiconductor device using a SAC etching process in accordance with the present invention.

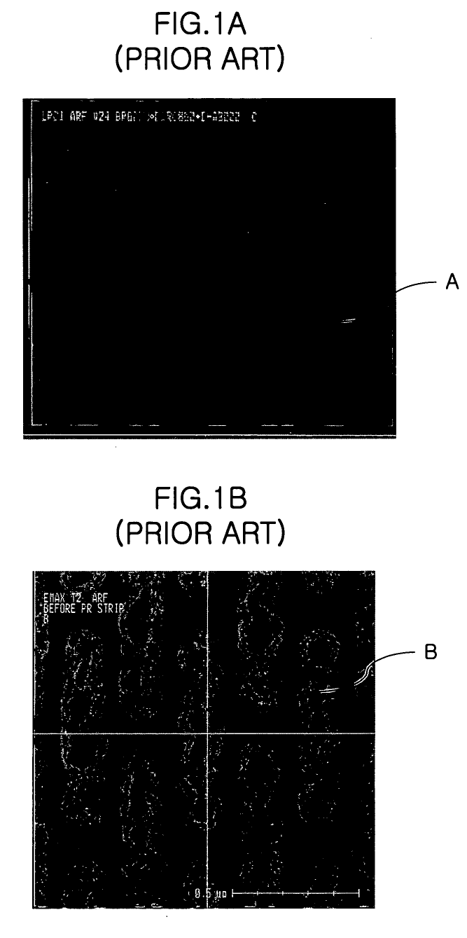

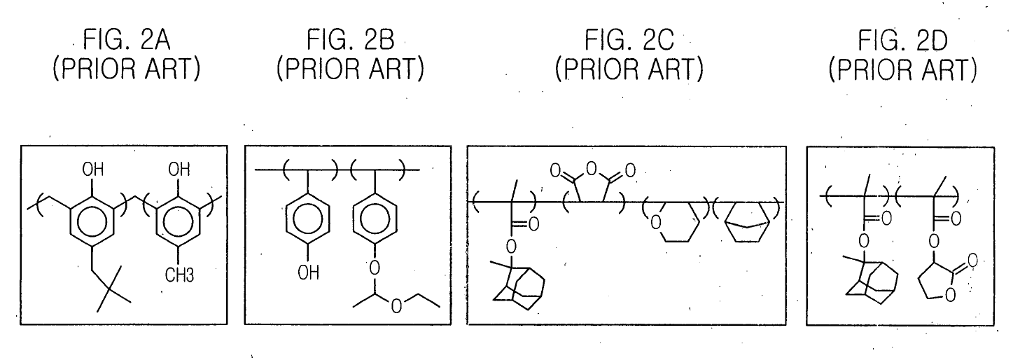

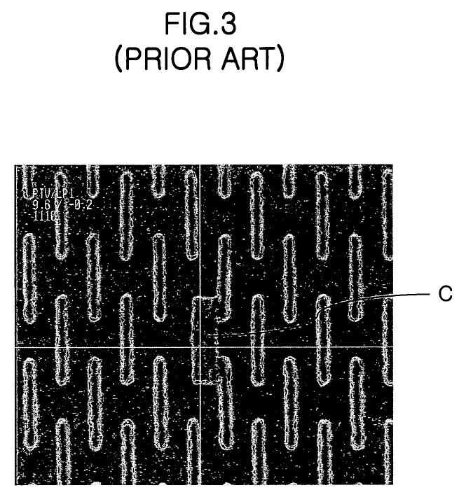

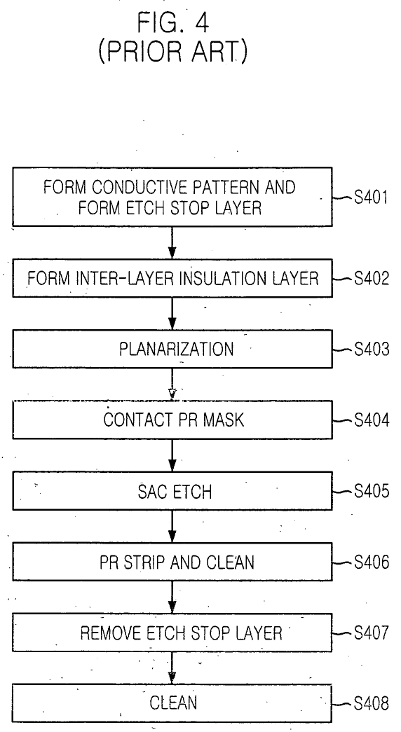

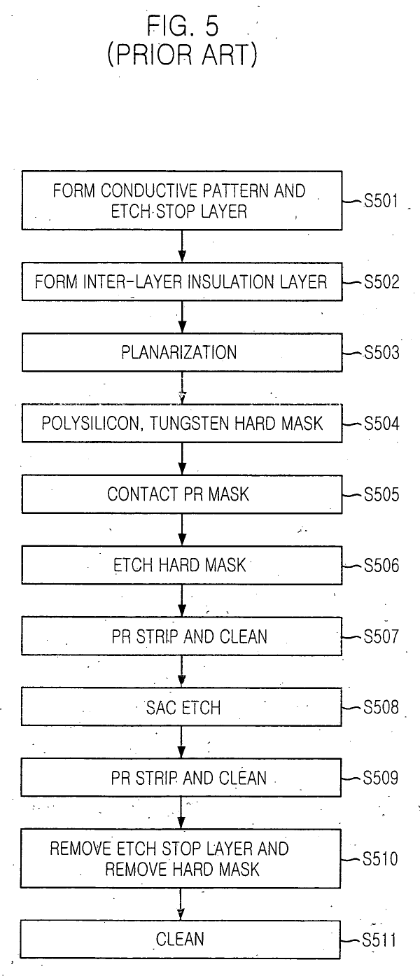

### DETAILED DESCRIPTION OF THE INVENTION

Hereinafter, a method for forming a plurality of contact holes in a semiconductor device in accordance with a preferred embodiment of the present invention will be explained in detail with reference to the accompanying drawings.

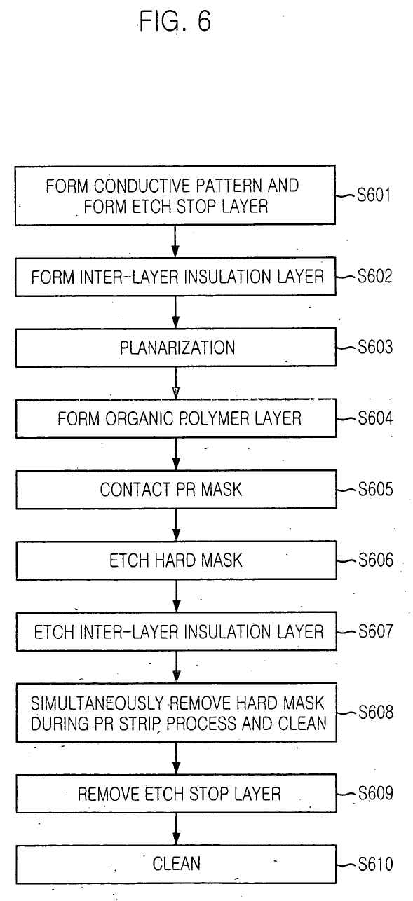

FIG. 6 is a flow chart illustrating a SAC etching process in accordance with the present invention. With reference to FIG. 6, the SAC etching process in accordance with the present invention will be explained.

First, a conductive pattern such as a gate electrode is formed and an etch stop layer is formed thereon at step S601. Subsequently, an inter-layer insulation layer is formed on a substrate provided with the conductive pattern and the etch stop layer at step S602. The inter-layer insulation layer is formed by using a typical oxide layer based material and the etch stop layer is formed by using a nitride layer based material having both insulation and a selective ratio to the oxide layer.

Subsequently, an upper portion of the inter-layer insulation layer is planarized during performing a photolithography process in order to prevent a pattern defect at step S603. At this time, the inter-layer insulation layer is removed until the etch stop layer is exposed or until the inter-layer insulation remains on the etch stop layer with a predetermined thickness in order to decrease a portion which will be etched by a subsequent SAC etching process.

Subsequently, an organic polymer layer which will be used as a hard mask is formed on the inter-layer insulation layer at step S604. The organic polymer layer has much higher selective ratio to the oxide layer than a polysilicon layer, a tungsten layer and a nitride layer. In case of using the organic polymer as the hard mask, there provides an effect of preventing a pattern deformation caused by a weak etch tolerance of the photoresist for ArF. Therefore, it is possible to lower a depositing thickness of the organic polymer layer and a thickness of the photoresist than a thickness of the organic polymer, thereby producing a much higher resolution.

Next, a photoresist (PR) mask, i.e., a photoresist pattern, for forming a contact hole is formed by performing a photolithography process using KrF, ArF or F₂ light source at step S605.

Next, the organic polymer layer for the hard mask is etched by using the photoresist pattern as an etch mask, thereby forming the hard mask defining a region where the contact hole is formed at step S606.

Subsequently, the inter-layer insulation layer is etched by using the hard mask as the etch mask, thereby forming the contact hole at step S607. At this time, the etch stop layer typically remains on a region where contact will be made.

Subsequently, a remaining photoresist pattern is removed through a PR strip process and an etch residual product and an etch by-product are removed through a cleaning process at step S608. Meanwhile, since the hard mask formed by using the organic polymer layer as described above has a similar structure with the photoresist pattern, the hard mask is simultaneously removed with the photoresist during the PR strip process.

Next, a contact open process removing the etch stop layer is employed and then, the hard mask is removed at step S609. Afterwards, the etch by-product generated during the contact open process is removed by employing the cleaning process at step S610.

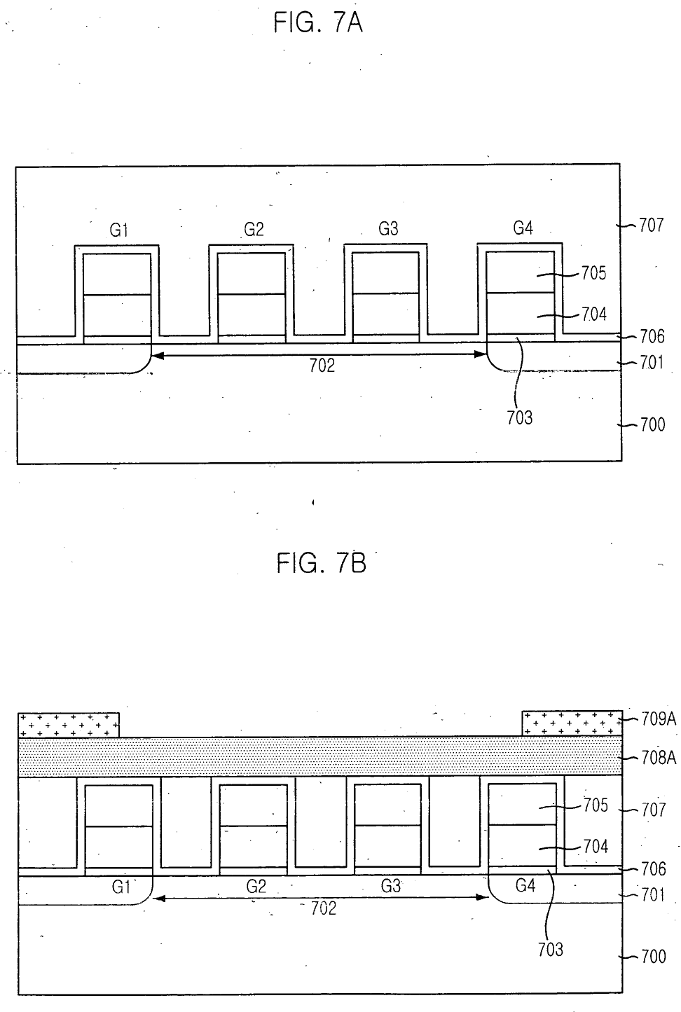

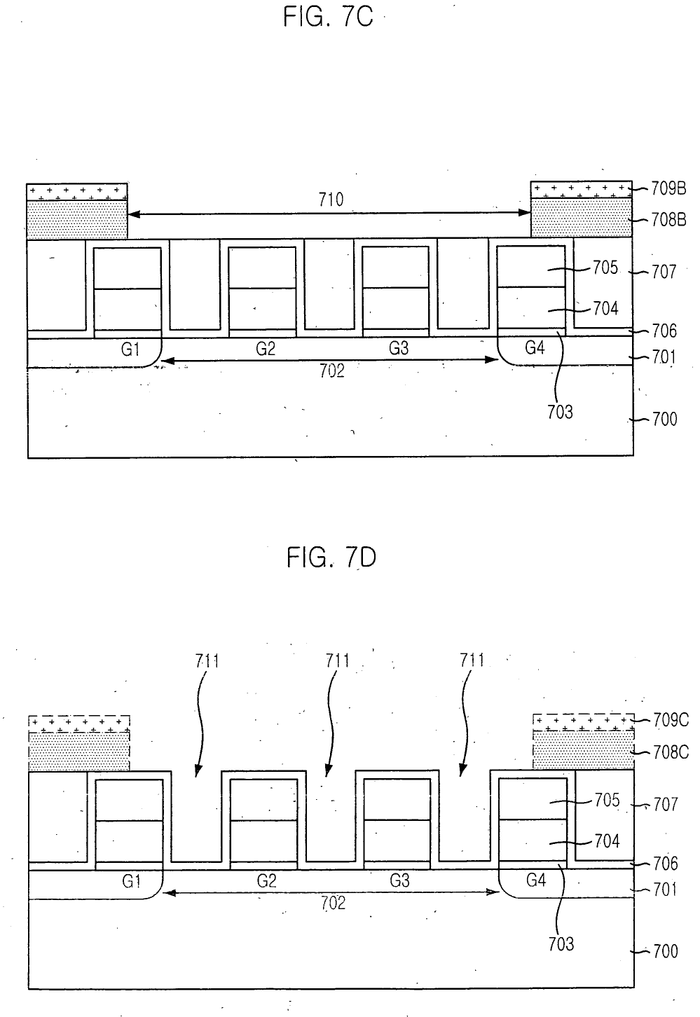

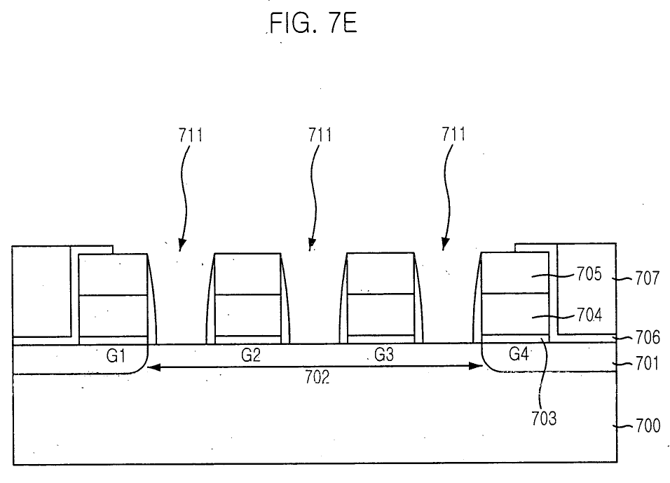

FIGS. 7A to 7E are diagrams illustrating a process for forming a contact hole for a cell contact of a semiconductor device by using a SAC etching process in accordance with the present invention.

Although the embodiment of the present invention exemplifies a process for forming a contact hole pattern of a semiconductor device, this contact hole pattern can be employed in another method for forming a metal interconnection line contact, a bit line contact or a storage node contact of a capacitor contacting to an impurity junction region such as a source/drain junction within a substrate and for forming a contact pad.

Furthermore, the present invention uses the SAC etching process in case of forming the contact hole; however, other etching processes for forming the contact hole also can be applied to the present invention.

First, referring to FIG. 7A, a field oxide layer 701 is formed on a substrate provided with various elements for forming a semiconductor device, thereby defining an active region 702. The field oxide layer 701 can be formed by using one of a local oxidation of silicon (LOCOS) method and a shallow trench isolation (STI) method.

Subsequently, a plurality of gate electrode patterns G1 to G4 formed by stacking a plurality of gate hard masks 705, gate conductive layers 704 and gate insulation layers having an insulation characteristic are formed on the substrate 700.

The plurality of insulation layers 703 are formed by using an oxide-based layer such as a silicon oxide layer and the plurality of gate conductive layers 704 are made of a material selected from a group consisting of polysilicon, tungsten (W), tungsten nitride (WNₓ), tungsten silicide (WSiₓ) or from a combination of the above listed materials.

The plurality of gate hard masks 705 are formed for preventing the plurality of gate conductive layers 704 from an attack by a step of etching the inter-layer insulation layer of a subsequent etching process for forming the contact hole. The plurality of gate hard masks 705 are made of a material having an apparently different etching speed from the inter-layer insulation layer. For instance, in case of using the oxide-based layer as the inter-layer insulation layer, the nitride-based layer such as a silicon nitride (SiN) layer or a silicon oxinitride (SiON) layer is used and in case of using a polymer based low permittivity layer as the inter-layer insulation layer, the oxide based material is used.

An impurities diffusion region (not shown) such as a source/drain junction is formed between the plurality of gate electrode patterns G1 to G4 on the substrate 700.

In case of forming the source/drain junction region between the plurality of gate electrode patterns G1 to G4 through ion implantation, impurities are typically implanted into the substrate 700 through the ion implantation in order to align the plurality of gate electrode patterns G1 to G4. Meanwhile, in case of a peripheral region as for a semiconductor device similar to a dynamic random access memory (DRAM) to which the semiconductor device in accordance with the present invention is belonged, a spacer is formed on a side wall of the plurality of gate electrode patterns G1 to G4 and then, the ion implantation is performed again, thereby forming a lightly doped drain (LDD) structure. In case of a cell region, only the ion implantation performed before forming the spacer is employed. Herein, the impurities diffusion region and a process for forming the spacer are omitted.

An etch stop layer 706 serving a role of an etch stop is formed in order to prevent the substrate 700 from an attack by an etch gas and a radical of the etch gas during a subsequent SAC etching process. At this time, it is preferable to form the etch stop layer 706 along a profile of the plurality of gate electrode patterns G1 to G4. The etch stop layer 706 is made of the nitride-based layer such as the SiN layer and the SiON layer by considering an etch selectivity to the inter-layer insulation layer mainly formed by using the oxide-based layer.

That is, a reason why the etch stop layer 706 is made of the nitride-based layer is because the nitride-based layer helps to obtain a desirable etch selectivity to the oxide layer used as the inter-layer insulation layer during the SAC etching process for forming a subsequent plug and to prevent the etch loss of the plurality of the gate electrode patterns.

Meanwhile, the etch stop layer 706 can be formed as a single layer as illustrated in FIG. 7A and as plurality layers. Furthermore, the nitride-based layer induces stress when the nitride-based layer directly contacts the substrate; and thus, the nitride-based layer can be formed with providing a buffer oxide layer at an interface between the nitride-based layer and the substrate.

Subsequently, an inter-layer insulation layer 707 is formed to sufficiently cover an upper portion of the substrate and the plurality of the gate electrode patterns G1 to G4. The inter-layer insulation layer 707 is made of a material selected from a group of a boro-phospho-silicate-glass (BPSG) layer, a boro-silicate-glass (BSG) layer, a phospho-silicate-glass (PSG) layer, a tetra-ethyl-ortho-silicate (TEOS) layer, a high-density-plasma (HDP) oxide layer, a low k-dielectric layer, a spin-on-glass (SOG) layer and an advanced-planarization layer (APL) or a combination of the above listed materials.

Subsequently, referring to FIG. 7B, an upper portion of the inter-layer insulation layer 707 is planarized until the etch stop layer 706 is exposed to prevent a pattern formation defect caused by an unevenness of a surface of the inter-layer insulation layer during a subsequent photolithography process and to reduce an etch target during the SAC etching process. Herein, the inter-layer insulation layer 707 does not remain on an upper portion of the etch stop layer 706; however, the inter-layer insulation layer 707 remains on the upper portion of the etch stop layer 706 up to a thickness of approximately 1,500 Å. The planarization is performed by employing a chemical mechanical polishing (CMP) process or an etch back process.

Next, an organic polymer layer 708A for the hard mask is formed on the planarized surface of the inter-layer insulation layer 707. An etch selectivity of the inter-layer insulation layer 707 with respect to the organic polymer layer 708A is almost infinite under the fluoride based gas. Therefore, it is preferable to use the organic polymer layer as the hard mask during a process for etching the inter-layer insulation layer 707, i.e., the SAC etching process, with use of the fluoride based gas.

Furthermore, due to the above explained etch selectivity, the organic polymer layer 708A can serve a role of the hard mask only with a relatively thin thickness ranging from approximately 200 Å to approximately 1,000 Å, thereby raising resolution.

Herein, silk or amorphous carbon (a-carbon) is an exemplary material to form the organic polymer layer 708A.

Subsequently, the photoresist is deposited on the organic polymer layer 708A with an appropriate thickness through a spin coating method. Then, predetermined portions of the photoresist are selectively photo-exposed by using KrF, ArF or F₂ light source and a predecided reticle (not shown) for defining a width of the contact hole. Thereafter, a developing process proceeds by making a photo-exposed portion or a non-photo-exposed portion remain, and a subsequent cleaning process is then performed to remove etch remnants, thereby forming a plurality of photoresist patterns 709A which are cell contact open masks for a SAC formation.

Herein, the cell contact open mask can use one of various types such as a hole type, a bar type or a T type.

During the photo-exposure process for forming the pattern, an anti-reflective layer (not shown) can be formed between the plurality of photoresist patterns 709A and a lower structure for purposes of preventing a formation of an undesired pattern caused by a scattered light and improving adhesiveness of the plurality of photoresist patterns 709A and the lower structures. The anti-reflective layer can be made of an organic-based material having a similar etch characteristic with the plurality of photoresist patterns 709A. However, the formation of the anti-reflective layer can be omitted depending on processes.

Referring to FIG. 7C, the organic polymer layer 708A is etched by using the plurality of photoresist patterns 709A as the etch mask and a plurality of hard masks 708B are formed, thereby defining a region 710 that will be etched for forming the contact hole.

At this time, the organic polymer layer 708A can be made of an O₂/N₂ plasma due to a characteristic of the organic polymer layer and herein, some parts of the plurality of photoresist patterns 709B are damaged because of a similar characteristic with the organic polymer layer 708A.

Subsequently, referring to FIG. 7D, the inter-layer insulation layer 707 is etched by using the plurality of photoresist patterns 709B and the plurality of hard masks 708B as the etch mask, thereby forming a plurality of contact holes 711 by performing the SAC etching process exposing the etch stop layer 706 between the plurality of the gate electrode patterns G1 to G4.

At this time, during the process etching the inter-layer insulation layer 707, a typical recipe for the SAC etching process is employed. That is, a fluoride based plasma, for instance, CₓF_{y} (x and y representing atomic ratios range from 1 to 10) such as C₃F₃, C₂F₄, C₂F₆, C₃F₈, C₄F₆, C₅F₈ or C₅F₁₀, is used as a main gas. A gas for generating polymer during the SAC process, i.e., CₐH_{b}F_{c} (a, b and C representing atomic ratios range from 1 to 10) such as CH₂F₂, C₃HF₅ or CHF₃, and O₂, is added therein. At this time, a non-active gas such as He, Ne, Ar or Xe is used as a carrier gas.

Subsequently, the plurality of photoresist patterns 709B are removed by employing a photoresist strip process and at this time, the plurality of hard masks 708B having a similar material characteristic with the plurality of photoresist patterns 709B are removed simultaneously.

Furthermore, in case of using the organic based anti-reflective layer between the plurality of photoresist patterns 709B and the plurality of hard masks 708B, the anti-reflective layer can be simultaneously removed since the anti-reflective layer is made of an organic based material.

Subsequently, referring to FIG. 7E, the substrate 700, i.e., the impurities diffusion region, is exposed by etching the etch stop layer 706. The etch stop layer 711 is etched by using a blanket etch or a separate mask.

At this time, the etch stop layer 706 is etched, thereby remaining with a spacer 706A shape on sides of the plurality of gate electrode patterns G1˜G4 formed with the plurality of contact holes 711.

As a subsequent process, a wet cleaning process is performed by using a cleaning solution such as buffered oxide etchant (BOE) in order to remove etch remnants remaining after the SAC etching process and the blanket etch process and to secure a critical dimension (CD) of each bottom portion of the plurality of contact holes 711. For the cleaning process, BOE or HF is used and in case of using HF, it is preferable to use a solution of HF diluted with water in a ratio of approximately 50 to approximately 500 parts of water to approximately 1 part of HF.

Furthermore, the conductive layer for a plug formation is formed on the substrate provided with the plurality of contact holes 711 by using a deposition or a growth method, thereby sufficiently burying the plurality of contact holes 711. Afterwards, a contact pad, i.e., a contact pad, is formed by performing an isolation process.

As explained above, the present invention uses an organic polymer layer as a hard mask during an etching process for forming a contact hole by etching an oxide layer and thus, makes it possible to produce a desirable fine pattern without a pattern deformation during etching the oxide layer by using a fluoride plasma due to an almost infinite etch selectivity with respect to the oxide layer having the organic polymer layer.

Also, the present invention can lower a thickness of the hard mask and a thickness of the photoresist, thereby producing a fine pattern with a size equal to or less than approximately 50 nm. Furthermore, the organic polymer layer has a similar characteristic with the photoresist and thus, the organic polymer layer can be removed at once. Therefore, the present invention makes a process simple since it is not necessary to have a separate additional process according to a removal of the hard mask.

For instance, although the preferred embodiment of the present invention exemplifies a SAC process of a T type, a SAC process of a line type or a hole type can be applied to the present invention. Also, a process for opening not only the plurality of gate electrode patterns but also the plurality of bit lines, i.e, a process for forming a storage node contact hole, or a process for forming a via contact are applied to the present invention.

As explained above, the present invention provides an effect of overcoming a limitation of an etch selectivity when forming a contact hole, thereby producing a pattern and the present invention can also omit a separate process for removing a hard mask, thereby providing an effect of simplifying a process.

The present application contains subject matter related to the Korean patent application No. KR 2004-0049891, filed in the Korean Patent Office on Jun. 30, 2004 the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A method for forming a plurality of contact holes in a semiconductor device, comprising the steps of:
forming an oxide-based layer on a substrate;
forming an organic polymer layer on the oxide-based layer;
forming a photoresist pattern on the organic polymer layer to form the plurality of contact holes;
etching the organic polymer layer by using the photoresist pattern as an etch mask, thereby forming a hard mask;
etching the oxide-based layer by using the photoresist pattern and the hard mask as an etch mask; and
removing the photoresist pattern and the hard mask by performing a photoresist strip process, thereby obtaining the plurality of contact holes.

2. The method of claim 1, wherein an etch selectivity of the oxide-based layer with respect to the organic polymer layer is almost infinite under a fluoride based gas.

3. The method of claim 1, wherein the organic polymer layer is formed with a thickness ranging from approximately 200 Å to approximately 1,000 Å.

4. The method of claim 1, the step of forming the hard mask includes a step of etching the organic polymer layer by using O₂/N₂ plasma.

5. The method of claim 1, wherein the organic polymer layer is formed by using one of silk and a-carbon.

6. The method of claim 4, wherein the step of etching the etch target layer uses CₓF_{y} where x and y representing atomic ratios range from 1 to 10, as a main etch gas along with gases of O₂ and CₐH_{b}F_{c} where a, b and c representing atomic ratios range from 1 to 10, and uses one of He, Ne, Ar and Xe as a carrier gas.

7. The method of claim 1, the step of forming the photoresist pattern uses a photolithography process by using one of KrF, ArF and F₂ light sources.

8. A method for forming a plurality of contact holes in a semiconductor device, comprising the steps of:
forming a plurality of conductive patterns on a conductive region;
forming an oxide-based inter-layer insulation layer on the resulting structure including the plurality of conductive patterns;
forming an organic polymer layer on the oxide-based inter-layer insulation layer;
forming a photoresist pattern on the organic polymer layer to form the plurality of contact holes;
etching the organic polymer layer by using the photoresist pattern as an etch mask, thereby forming a hard mask;
etching the inter-layer insulation layer with use of the photoresist pattern and the hard mask as the etch mask; and
removing the photoresist pattern and the hard mask by performing a photoresist strip process, thereby obtaining the plurality of contact holes.

9. The method of claim 8, wherein the organic polymer layer is formed with a thickness ranging from approximately 200 Å to approximately 1,000 Å.

10. The method of claim 8, wherein the step of forming the hard mask includes a step of etching the organic polymer layer by using O₂/N₂ plasma.

11. The method of claim 8, wherein after the step of forming the oxide-based inter-layer insulation layer, the oxide-based inter-layer insulation layer is planarized until the oxide-based inter-layer insulation layer remains on an upper portion of the conductive pattern in a thickness ranging from approximately 0 Å to approximately 1,500 Å.

12. The method for claim 10, wherein the step of etching the oxide-based inter-layer insulation layer uses CₓF_{y}, where x and y representing atomic ratios range from 1 to 10, as a main etch gas along with gases of O₂ and CₐH_{b}F_{c} where a, b and c representing atomic ratios range from 1 to 10, and uses one of He, Ne, Ar and Xe as a carrier gas.

13. The method for claim 8, wherein after the step of forming the organic polymer layer, an organic based anti-reflective layer is formed between the organic polymer layer and the photoresist pattern.

14. The method for claim 8, wherein a pattern type of the plurality of contact holes is one of a bar type, a hole type and a T-type.

15. A method for forming a plurality of contact holes in a semiconductor device, comprising the steps of:
forming a plurality of gate electrode patterns on a substrate;
forming a nitride-based etch stop layer on the resulting structure including the plurality of gate electrode patterns;
forming an oxide-based inter-layer insulation layer on the resulting structure including the nitride-based etch stop layer;
forming an organic polymer layer on the oxide-based inter-layer insulation layer;
forming a photoresist pattern on the organic polymer layer as a contact mask;
forming the organic polymer layer by using the photoresist pattern as an etch mask, thereby obtaining a hard mask;
etching the oxide-based inter-layer insulation layer by using the photoresist pattern and the hard mask as an etch mask;
removing the photoresist pattern and the hard mask by employing a photoresist strip process; and
opening the substrate within the plurality of contact holes by removing the nitride-based etch stop layer, thereby obtaining the plurality of contact holes.

16. The method of claim 15, wherein the organic polymer layer is formed in a thickness ranging from approximately 200 Å to approximately 1,000 Å.

17. The method for claim 15, wherein the step of forming the hard mask includes a step of etching the organic polymer layer by using O₂/N₂ plasma.

18. The method for claim 15, wherein after the step of forming the oxide-based inter-layer insulation layer, the oxide-based inter-layer insulation layer is planarized until the oxide-based inter-layer insulation layer remains on an upper portion of the gate electrode patterns in a thickness ranging from approximately 0 Å to approximately 1,500 Å.

19. The method of claim 17, wherein the step of etching the oxide-based inter-layer insulation layer uses CₓF_{y}, wherein x and y representing atomic ratios range from approximately 1 to approximately 10, as a main etch gas along with gases of O₂ and CₐH_{b}F_{c} where a, b and c representing atomic ratios range from 1 to 10, and uses one of He, Ne, Ar and Xe as a carrier gas.

20. The method of claim 15, wherein the step of forming the photoresist pattern uses a photolithography process by using one of KrF, ArF and F₂ light sources.

21. The method of claim 15, wherein after forming the organic polymer layer, an organic anti-reflective layer is formed between the organic polymer layer and the photoresist pattern.

22. The method of claim 15, wherein a pattern formation of the plurality of contact holes is one of a bar type, a T-type and a hole type.
